(19) United States
(12) Patent Application Publication
(10) Pub. No.: US 2009/0236979 A1
(43) Pub. Date: Sep. 24, 2009

(54) Organic Electroluminescent Device and the Method of Making

(75) Inventors: Gang Chris Han-Adebekun, Center Valley, PA (US); Xuezhong Jiang, Fogelsville, PA (US); Denise Luise Lindenmuth, North Wales, PA (US); Fabrice Amy, Macungie, PA (US)

Correspondence Address: AIR PRODUCTS AND CHEMICALS, INC.;PATENT DEPARTMENT, 7201 HAMILTON BOULEVARD, ALLENTOWN, PA, 181951501, US

(73) Assignee: AIR PRODUCTS AND CHEMICALS, INC., Allentown, PA (US)

(21) Appl. No.: 12/403,511

(22) Filed: Mar. 13, 2009

Related U.S. Application Data
(60) Provisional application No. 61/038,861, filed on Mar. 24, 2008.

(51) Int. Cl. H01J 1/62; H01L 51/56

(52) U.S. Cl. 313/504; 438/34; 257/E51.022

(57) ABSTRACT

The light-emitting device comprising an anode, a cathode, a semi-conducting layer between the anode and the cathode and a hole injection layer comprising a conducting polymer between the anode and the semi-conducting layer; where an interfacial bonding layer is formed in-situ between the hole injection layer and the semi-conducting is disclosed.

This Application claims the benefit of U.S. Provisional Application No. 61/038,861, filed on Mar. 24, 2008. The disclosure of the Provisional Application is hereby incorporated by reference.

### BACKGROUND OF THE INVENTION

In light-emitting device design and manufacturing, it is known that interfacial properties of various layers within the multiple layers device structure can be important for optimal device performance. These interfacial properties can include: A) the boundary structure between conductive polymer and semi-conducting polymer layers, B) matching the surface energy of the liquid deposited and the surface energy of the solid film surface being deposited on for good wetting and film formation, and C) interfacial adhesion and bonding between adjacent layers

A common understanding in OLED device field is that a clean boundary between conductive polymer and semi-conducting polymer layers is needed for the best device performance. As stated in Chapter 8 in “Organic Light-Emitting materials and Devices” (A CRC Press Book Taylor & Francis Group, 2007, Edited by Zhigang Li et al.), blending of the two polymers at the interface is detrimental for OLED device resulting in electroluminescence quenching and possible shorting. Therefore, a common step in current device manufacturing processes include a drying/annealing step for each layer in order to remove the residual water and solvent thus presenting the interlayer blending. U.S. Patent Application 2006/0251886A1 disclosed the use of crosslinking agents in the polymeric buffer layer followed by a crosslinking process by thermal or UV treatment. This is to prevent polymer solubilizaiton into the adjacent layer and thus minimize the interlayer blending.

WO 2007/031923 discloses a process for making a light-emitting device comprising an anode; a cathode; a light-emitting layer arranged between the anode and the cathode; and a buffer layer, comprising a conducting polymer and a polymeric acid, arranged between the anode and the light-emitting layer. An interfacial layer is formed between the buffer layer and the light-emitting layer by converting the polymeric acid to non-acidic groups through thermal treatment at elevated temperature which minimizes acid quenching of photoluminescence. However, this disclosure teaches using the conventional wet on dry process and did not address the generation of interfacial bonding layer for better layer adhesion.

An earlier study by Jiang et al (SPIE 2006 proceeding) titled “Enhanced Lifetime of Polymer Light-Emitting Diodes Using Poly(thieno[3,4-b]thiophene) base Conductive Polymers” concluded that conducting polymer with the colloid-forming polymeric acid comprises a highly-fluorinated sulfonic acid polymer (“FSA polymer”) has better thermal stability and low moisture residue as compared to conducting polymer with the water soluble colloid-forming polymeric acid such as poly(styrene sulfonic acid) (PSSA). This may be one of the key factors leading to longer device lifetime, especially under high temperature and high humidity conditions. However, a conductive polymer dispersion comprising the highly-fluorinated sulfonic acid polymer (such as NAFION® fluoropolymer), forms films with relatively low surface energy as compared to PSSA based conductive polymer. Therefore, there is a need in this art for a combination of materials having improved film wetting properties that are suitable to produce long lasting light emitting devices.

The previously identified patents and patent applications are hereby incorporated by reference.

### SUMMARY OF THE INVENTION

The instant invention solves problems associated with conventional materials and process by providing a wet-on-wet process for manufacturing a multiple layer electronic device (e.g., an OLED), wherein a first layer is deposited and a second layer is deposited upon the first layer before final thermal annealing. This process has the advantage of reduced TAC time and process cost. Further, the interfacial properties between wet on wet coated layers are improved leading to improved device performance such as reduced leakage current and better wetting of the film.

One aspect of the present invention relates to a light-emitting device comprising an anode, a cathode, a semiconducting layer between the anode and the cathode and a hole injection layer comprising a conducting polymer between the anode and the semi-conducting layer; where an interfacial bonding layer is formed in-situ between the hole injection layer and the semi-conducting layer. The interfacial bonding area can comprise a mixture of the hole injection layer and the semi-conducting layer. The interfacial bonding area can also comprise a gradient wherein a portion of the area adjacent to the hole injection layer is relatively concentrated in hole injection layer material and a portion of the area adjacent to the semi-conducting layer is relatively concentrated in semi-conducting layer material.

Another aspect of the present invention relates to a method for manufacturing a light-emitting device comprising: a) providing an anode, b) depositing a conducting polymer on the anode to form a hole-injection layer, b) depositing the semi-conducting layer on the hole injection layer, and c) applying these layers at elevated temperature to form an interfacial bonding layer between the hole injection layer and the semi-conducting layer, d) providing a cathode,

The direct benefits of the present wet on wet device making process as compared to the conventional wet on dry process can include, for example, reducing TAC time, reducing processing cost and increasing production line productivity through-put thereby leading to cost reduction for the final device.

An additional benefit of the present invention is improved device performance such as reduced leakage current in a typical IVB curve. In general, a high leakage current reduces the efficient use of the electrons which are needed to combine with the holes in the light emitting polymer layer to produce photons and thus light. Devices having relatively high leakage current lead to poor device performance as illustrated by the reduced current efficiency and pixel edge emission leading to enlarged pixels and poor resolution.

A further benefit of the present invention is the improved interfacial adhesion between conductive polymer layer (layer B) and semi-conducting polymer layer (Layer C) as illustrated in FIG. 2, and in FIG. 3 by the in-situ generation of an interfacial bonding layer between the above two layers

Another benefit of the present invention is that the inventive process allows the deposition of liquid on materials which have an inherent low surface energy (<30 dyns/cm) and thus poor wetting characteristics (e.g., if these materials can form solid surface or film of increased surface energy under dynamically controlled conditions such as drying rate control).

### CROSS REFERENCE TO RELATED PATENTS AND PATENT APPLICATIONS

The subject matter of the instant invention is related to U.S. patent application Ser. Nos. 11/240,573 and 11/760,000. The disclosure of the previously identified patent applications is hereby incorporated by reference.

### BRIEF DESCRIPTION OF THE DRAWINGS

FIG. 1 illustrates an cross-sectional view of an electronic device that includes a hole injection layer formed in accordance with a wet on wet process of one aspect of the invention.

FIG. 2 illustrates a conventional wet on dry process for making light-emitting device with device layer structure

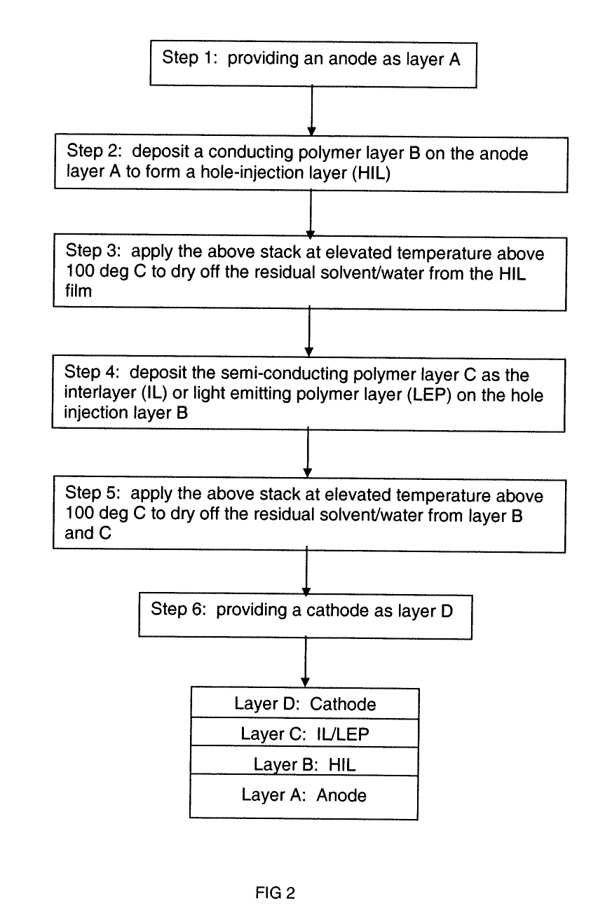

FIG. 3 illustrates a schematic of one aspect of the inventive wet on wet process for making light-emitting device with device layer structure.

### DETAILED DESCRIPTION OF THE INVENTION

The present disclosure relates to aqueous dispersions of electrically conductive polymers, methods for applying such dispersions, and devices incorporating conductive polymer containing films. The inventive conductive polymer dispersions may comprise heterocyclic fused ring monomer units, such as, but not limited to, polythiophenes including poly(3,4-ethylenedioxythiophene), polythienothiophenes, including, poly(thieno[3,4-b]thiophenes), mixtures thereof, among others. The dispersion also includes an at least partially fluorinated polymer. As used herein, the term “dispersion” refers to a liquid medium comprising a suspension of minute colloid particles. In accordance with the invention, the “liquid medium” is typically an aqueous liquid, e.g., de-ionized water. As used herein, the term “aqueous” refers to a liquid that has a significant portion of water and in one embodiment it is at least about 40% by weight water. As used herein, the term “colloid” refers to the minute particles suspended in the liquid medium, said particles having a particle size up to about 1 micron (e.g., about 20 nanometers to about 800 nanometers and normally about 30 to about 500 nanometers).

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of the “a” or “an” are employed to describe elements and components of the invention. This is done merely for convenience and to give a general sense of the invention. This description should be read to include one or at least one and the singular also includes the plural unless it is obvious that it is meant otherwise.

The electrically conductive polymer may include polymerized units of heterocyclic fused ring monomer units. The conductive polymer can be a polyaniline, polypyrroles or polythieophene and their derivatives.

Polypyrroles contemplated for use can have a composition comprising the Formula I:

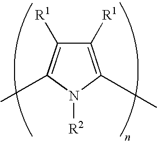

where in Formula I, n is at least about 4; R1 is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, amidosulfonate, benzyl, carboxylate, ether, ether carboxylate, ether sulfonate, and urethane; or both R1 groups together may form an alkylene or alkenylene chain completing a 3, 4, 5, 6, or 7-membered aromatic or alicyclic ring, which ring may optionally include one or more divalent nitrogen, sulfur or oxygen atoms; and R2 is independently selected so as to be the same or different at each occurrence and is selected from hydrogen, alkyl, alkenyl, aryl, alkanoyl, alkylthioalkyl, alkylaryl, arylalkyl, amino, epoxy, silane, siloxane, alcohol, amidosulfonate, benzyl, carboxylate, ether, ether carboxylate, ether sulfonate, sulfonate, and urethane.

In one aspect, R1 is the same or different at each occurrence and is independently selected from hydrogen, alkyl, alkenyl, alkoxy, cycloalkyl, cycloalkenyl, alcohol, amidosulfonate, benzyl, carboxylate, ether, ether carboxylate, ether sulfonate, sulfonate, urethane, epoxy, silane, siloxane, and alkyl substituted with one or more of sulfonic acid, carboxylic acid, acrylic acid, phosphoric acid, phosphonic acid, halogen, nitro, cyano, hydroxyl, epoxy, silane, or siloxane moieties.

In one aspect, R2 is selected from hydrogen, alkyl, and alkyl substituted with one or more of sulfonic acid, carboxylic acid, acrylic acid, phosphoric acid, phosphonic acid, halogen, cyano, hydroxyl, epoxy, silane, or siloxane moieties.

In one aspect, the polypyrrole is unsubstituted and both R1 and R2 are hydrogen.

In one aspect, both R1 together form a 6- or 7-membered alicyclic ring, which is further substituted with a group selected from alkyl, heteroalkyl, alcohol, amidosulfonate, benzyl, carboxylate, ether, ether carboxylate, ether sulfonate, sulfonate, and urethane. These groups can improve the solubility of the monomer and the resulting polymer. In one embodiment, both R1 together form a 6- or 7-membered alicyclic ring, which is further substituted with an alkyl group. In one embodiment, both R1 together form a 6- or 7-membered alicyclic ring, which is further substituted with an alkyl group having at least 1 carbon atom.

In one aspect, both R1 together form —O—(CHY)m—O—, where m is 2 or 3, and Y is the same or different at each occurrence and is selected from hydrogen, alkyl, alcohol, amidosulfonate, benzyl, carboxylate, ether, ether carboxylate, ether sulfonate, sulfonate, and urethane. In one aspect, at least one Y group is not hydrogen. In one embodiment, at least one Y group is a substituent having F substituted for at least one hydrogen. In one aspect, at least one Y group is perfluorinated.

In one aspect, the polypyrrole used in the new composition is a positively charged conductive polymer where the positive charges are balanced by the colloidal polymeric acid anions.

Polythiophenes contemplated for use in the present invention can have a composition comprising Formula II below:

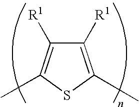

wherein: R1 is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, amidosulfonate, benzyl, carboxylate, ether, ether carboxylate, ether sulfonate, and urethane; or both R1 groups together may form an alkylene or alkenylene chain completing a 3, 4, 5, 6, or 7-membered aromatic or alicyclic ring, which ring may optionally include one or more divalent nitrogen, sulfur or oxygen atoms, and n is at least about 4.

In one aspect, both R1 together form —O—(CHY)m—O—, where m is 2 or 3, and Y is the same or different at each occurrence and is selected from hydrogen, alkyl, alcohol, amidosulfonate, benzyl, carboxylate, ether, ether carboxylate, ether sulfonate, and urethane. In one aspect, all Y are hydrogen. In one embodiment, the polythiophene is poly(3,4-ethylenedioxythiophene) or PEDOT. In one aspect, at least one Y group is not hydrogen. In one embodiment, at least one Y group is a substituent having F substituted for at least one hydrogen. In one aspect, at least one Y group is perfluorinated.

In one aspect, the polythiophene is a poly[(sulfonic acid-propylene-ether-methylene-3,4-dioxyethylene)thiophene]. In one aspect, the polythiophene comprises a poly[(propyl-ether-ethylene-3,4-dioxyethylene)thiophene].

In one aspect of the present invention, the invention provides monomeric, oligomeric and polymeric compositions having repeating unit having formula P1, as follows:

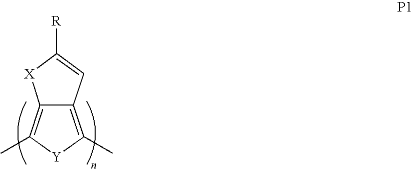

wherein X is S or Se, Y is S or Se, R is a substituent group. n is greater than about 2 and less than 20 and normally about 4 to about 16. R may be any substituent group capable of bonding to the ring structure of P1. R may include hydrogen or isotopes thereof, hydroxyl, alkyl, including C₁ to C₂₀ primary, secondary or tertiary alkyl groups, arylalkyl, alkenyl, perfluoroalkyl, perfluororaryl, aryl, alkoxy, cycloalkyl, cycloalkenyl, alkanoyl, alkylthio, aryloxy, alkylthioalkyl, alkynyl, alkylaryl, arylalkyl, amido, alkylsulfinyl, alkoxyalkyl, alkylsulfonyl, aryl, arylamino, diarylamino, alkylamino, dialkylamino, arylarylamino, arylthio, heteroaryl, arylsulfinyl, alkoxycarbonyl, arylsulfonyl, carboxyl, halogen, nitro, cyano, sulfonic acid, or alkyl or phenyl substituted with one or more sulfonic acid (or derivatives thereof), phosphoric acid (or derivatives thereof), carboxylic acid (or derivatives thereof), halo, amino, nitro, hydroxyl, cyano or epoxy moieties. In certain embodiments R may include alpha reactive sites, wherein branched oligomeric, polymeric or copolymeric structures of the selenium containing ring structure may be formed. In certain aspects, R may include hydrogen, alkylaryl, arylalkyl, aryl, heteroaryl, C₁ to C₁₂ primary, secondary or tertiary alkyl groups, which may be mono- or polysubstituted by F, Cl, Br, I or CN, and wherein one or more non-adjacent CH2 groups may be replaced, independently with —O—, —S—, —NH—, —NR′—, —SiR′R″—, —CO−, —COO—, —OCO—, —OCO—O—, —S—CO—, —CO—S—, —CH═CH— or —C≡C— in such a manner that O and/or S atoms are not linked directly to one another, phenyl and substituted phenyl groups, cyclohexyl, naphthalenic, hydroxyl, alkyl ether, perfluoroalkyl, perfluoroaryl, carboxylic acids, esters and sulfonic acid groups, perfluoro, SF₅, or F. R′ and R″ are independently of each other H, aryl or alkyl with 1 to 12 C-atoms. The polymer can include end-groups independently selected from functional or non-functional end-groups. The repeating structures according to the present invention may be substantially identical, forming a homopolymer, or may be copolymeric nature by selecting monomers suitable for copolymerization. The repeating unit may be terminated in any suitable manner known in the art and may include functional or non-functional end groups. In addition, dispersions and solutions containing P1 and polymeric acid doped compositions of P1. In one embodiment, the composition includes an aqueous dispersion of a polymeric acid doped polymer according to P1.

In one aspect of the disclosure, aqueous dispersions comprising electrically conductive polythienothiophenes such as poly(thieno[3,4-b]thiophene) can be prepared when thienothiophene monomers including thieno[3,4-b]thiophene monomers, are polymerized chemically in the presence of at least one partially fluorinated polymeric acid. The dispersion of polythienothiophene according to the present disclosure includes a film forming additive. The film forming additive has a boiling point of less than about 850 (and provides a dynamic surface tension of 100 milliseconds (ms) of less than 60 dynes/cm. The total concentration of the film forming additive is less than the solubility limit of the additive in water.

Compositions according to one aspect of the invention comprise a continuous aqueous phase in which the poly(thienothiophene) and dispersion-forming partially fluorinated polymeric acid are dispersed. Poly(thienothiophenes) that can be used in the present invention can have the structure (1) and (2):

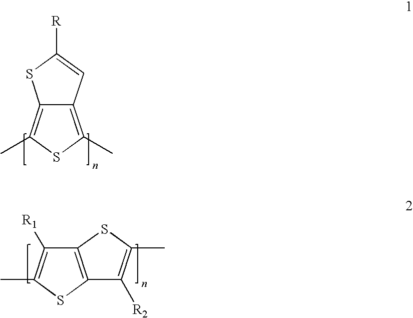

wherein R is selected from hydrogen, an alkyl having 1 to 8 carbon atoms, phenyl, substituted phenyl, CₘF₂ₘ₊₁, F, Cl, and SF₅, and n is greater than about 2 and less than 20 and normally about 4 to about 16.

Thienothiophenes that can be used in the compositions of this invention may also have the structure (2) as provided above, wherein R₁ and R₂ are independently selected from the list above. In one particular aspect, the polythienothiophene comprises poly(thieno[3,4-b]thiophene) wherein R comprises hydrogen.

Another aspect of the invention includes the conductive polymer poly(selenolo[2,3-c]thiophene). The polymers for use with this disclosure may include copolymers further comprising polymerized units of an electroactive monomer. Electroactive monomers may be selected from the group consisting of thiophenes, thieno[3,4-b]thiophene, thieno[3,2-b]thiophene, substituted thiophenes, substituted thieno[3,4-b]thiophenes, substituted thieno[3,2-b]thiophene, dithieno[3,4-b:3′,4′-d]thiophene, selenophenes, substituted selenophenes, pyrrole, bithiophene, substituted pyrroles, phenylene, substituted phenylenes, naphthalene, substituted naphthalenes, biphenyl and terphenyl, substituted terphenyl, phenylene vinylene, substituted phenylene vinylene, fluorene, substituted fluorenes. In addition to electroactive monomers, the copolymers according to the present invention may include polymerized units of a non-electroactive monomers. Examples of selenium containing monomers and polymers are disclosed in U.S. application Ser. No. 12/353,609, filed on Jan. 14, 2009 and Ser. No. 12/353,461, filed on Jan. 14, 2009; the disclosures of which are hereby incorporated by reference.

Polyaniline compounds which can be used in the present invention can be obtained from aniline monomers having Formula III below:

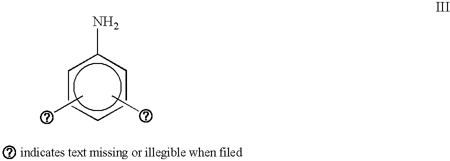

wherein n is an integer from 0 to 4; m is an integer from 1 to 5, with the proviso that n+m=5; and R1 is independently selected so as to be the same or different at each occurrence and is selected from alkyl, alkenyl, alkoxy, cycloalkyl, cycloalkenyl, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, carboxylic acid, halogen, cyano, or alkyl substituted with one or more of sulfonic acid, carboxylic acid, halo, nitro, cyano or epoxy moieties; or any two R1 groups together may form an alkylene or alkenylene chain completing a 3, 4, 5, 6, or 7-membered aromatic or alicyclic ring, which ring may optionally include one or more divalent nitrogen, sulfur or oxygen atoms.

The polymerized material comprises aniline monomer units, each of the aniline monomer units having a formula selected from Formula IV below:

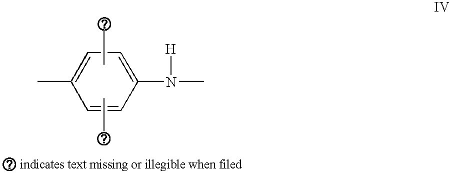

or Formula V below:

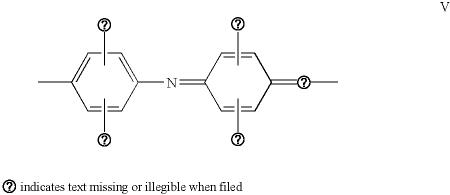

wherein n, m, and R1 are as defined above. In addition, the polyaniline may be a homopolymer or a co-polymer of two or more aniline monomeric units.

The compositions of the present invention are not limited to the homopolymeric structures above and may include hetereopolymeric or copolymeric structures. The copolymeric structures may be any combination of alternating copolymers(e.g., alternating A and B units), periodic copolymers (e.g., (A-B-A-B-B-A-A-A-A-B-B-B)n), random copolymers (e.g., random sequences of monomer A and B), statistical copolymers (e.g., polymer sequence obeying statistical rules) and/or block copolymers (e.g., two or more homopolymer subunits linked by covalent bonds). The copolymers may be branched or linked, provided the resultant copolymer maintains the properties of electrical conductivity.

Dispersion polymeric acids contemplated for use in the practice of the invention are insoluble in water, and may form colloids when dispersed into a suitable aqueous medium. The polymeric acids typically have a molecular weight in the range of about 10,000 to about 4,000,000. In one aspect, the polymeric acids have a molecular weight of about 50,000 to about 2,000,000. Other acceptable polymeric acids comprise at least one member of polymer phosphoric acids, polymer carboxylic acids, and polymeric acrylic acids, and mixtures thereof, including mixtures having partially fluorinated polymeric acids. In another aspect, the polymeric sulfonic acid comprises a fluorinated acid. In still another aspect, the colloid-forming polymeric sulfonic acid comprises a perfluorinated compound. In yet another aspect, the colloid-forming polymeric sulfonic acid comprises a perfluoroalkylenesulfonic acid.

In still another aspect, the colloid-forming polymeric acid comprises a highly-fluorinated sulfonic acid polymer (“FSA polymer”). “Highly fluorinated” means that at least about 50% of the total number of halogen and hydrogen atoms in the polymer are fluorine atoms, and in one embodiment at least about 75%, and in another embodiment at least about 90%. In one embodiment, the polymer comprises at least one perfluorinated compound.

The polymeric acid can comprise sulfonate functional groups. The term “sulfonate functional group” refers to either sulfonic acid groups or salts of sulfonic acid groups, and in one embodiment comprises at least one of alkali metal or ammonium salts. The functional group is represented by the formula —SO₃X where X comprises a cation, also known as a “counterion”. X can comprise at least one member selected from the group consisting of H, Li, Na, K or N(R₁)(R₂)(R₃)(R₄), and R₁, R₂, R₃, and R₄ are the same or different, and are in one embodiment H, CH₃ or C₂H₅. In another embodiment, X comprises H, in which case the polymer is said to be in the “acid form”. X may also be multivalent, as represented by such ions as Ca²⁺, Al³⁺, Fe²⁺ and Fe³⁺. In the case of multivalent counterions, represented generally as Mⁿ⁺, the number of sulfonate functional groups per counterion will be equal to the valence “n”.

In one embodiment, the FSA polymer comprises a polymer backbone with recurring side chains attached to the backbone, the side chains carrying cation exchange groups. Polymers include homopolymers or copolymers of two or more monomers. Copolymers are typically formed from a nonfunctional monomer and a second monomer carrying a cation exchange group or its precursor, e.g., a sulfonyl fluoride group (—SO₂F), which can be subsequently hydrolyzed to a sulfonate functional group. For example, copolymers comprising a first fluorinated vinyl monomer together with a second fluorinated vinyl monomer having a sulfonyl fluoride group (—SO₂F) can be used. Examples of suitable first monomers comprise at least one member from the group of tetrafluoroethylene (TFE), hexafluoropropylene, vinyl fluoride, vinylidine fluoride, trifluoroethylene, chlorotrifluoroethylene, perfluoro(alkyl vinyl ether), and combinations thereof. TFE is a desirable first monomer.

In other aspects, examples of second monomers comprise at least one fluorinated vinyl ether with sulfonate functional groups or precursor groups which can provide the desired side chain in the polymer. Additional monomers, including ethylene. In one embodiment, FSA polymers for use in the present invention comprise at least one highly fluorinated FSA, and in one embodiment perfluorinated, carbon backbone and side chains represented by the formula

—(O—CF₂CFR_{f})ₐ—O—CF₂CFR′_{f}SO₃X

wherein R_{f} and R′_{f} are independently selected from F, Cl or a perfluorinated alkyl group having 1 to 10 carbon atoms, a=0, 1 or 2, and X comprises at least one of H, Li, Na, K or N(R₁)(R₂)(R₃)(R₄) and R₁, R₂, R₃, and R₄ are the same or different and are and in one embodiment H, CH₃ or C₂H₅. In another embodiment X comprises H. As stated above, X may also be multivalent.

In another embodiment, the FSA polymers include, for example, polymers disclosed in U.S. Pat. Nos. 3,282,875, 4,358,545 and 4,940,525 (all hereby incorporated by reference in their entirety). An example of a useful FSA polymer comprises a perfluorocarbon backbone and the side chain represented by the formula

—O—CF₂CF(CF₃)—O—CF₂CF₂SO₃X

where X is as defined above. FSA polymers of this type are disclosed in U.S. Pat.

No. 3,282,875 and can be made by copolymerization of tetrafluoroethylene (TFE) and the perfluorinated vinyl ether CF₂═CF—O—CF₂CF(CF₃)—O—CF₂CF₂SO₂F, perfluoro(3,6-dioxa-4-methyl-7-octenesulfonyl fluoride) (PDMOF), followed by conversion to sulfonate groups by hydrolysis of the sulfonyl fluoride groups and ion exchanged as necessary to convert them to the desired ionic form. An example of a polymer of the type disclosed in U.S. Pat. Nos. 4,358,545 and 4,940,525 has the side chain —O—CF₂CF₂SO₃X, wherein X is as defined above. This polymer can be made by copolymerization of tetrafluoroethylene (TFE) and the perfluorinated vinyl ether CF₂═CF—O—CF₂CF₂SO₂F, perfluoro(3-oxa-4-pentenesulfonyl fluoride) (POPF), followed by hydrolysis and further ion exchange as necessary.

In another embodiment, the FSA polymers include, for example, polymers disclosed in US 2004/0121210 Al; hereby incorporated by reference in its entirety. 25 An example of a useful FSA polymer can be made by copolymerization of tetrafluoroethylene (TFE) and the perfluorinated vinyl ether CF₂═CF—O—CF₂CF₂CF₂CF₂SO₂F followed by conversion to sulfonate groups by hydrolysis of the sulfonyl fluoride groups and ion exchanged as desired to convert the fluoride groups to the desired ionic form. In another embodiment, the FSA polymers include, for example, polymers disclosed in US2005/0037265 A1; hereby incorporated by reference in its entirety. An example of a useful FSA polymer can be made by copolymerization of CF₂═CFCF₂OCF₂CF₂SO₂F and tetrafluoroethylene followed by conversion to sulfonate groups by KOH hydrolysis of the sulfonyl fluoride groups and ion exchanged with acid to convert the potassium ion salt to the acid form.

Aqueous dispersions comprising colloid-forming polymeric acids, including FSA polymers, typically have particle sizes as small as possible, so long as a stable colloid is formed. Aqueous dispersions of FSA polymer are available commercially as NAFION® dispersions, from E. I. du Pont de Nemours and Company (Wilmington, Del.). An example of a suitable FSA polymer comprises a copolymer having a structure:

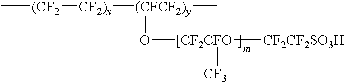

The copolymer comprises tetrafluoroethylene and perfluoro(4-methyl-3,6-dioxa-7-octene-1-sulfonic acid) wherein m=1.

Aqueous dispersions of FSA polymer from US2004/0121210 A1 or US2005/0037265 A1 could be made by using the methods disclosed in U.S. Pat. No. 6,150,426; the disclosure of the previously identified U.S. patents and patent applications is hereby incorporated by reference in their entirety.

Other suitable FSA polymers are disclosed in U.S. Pat. No. 5,422,411; hereby incorporated by reference in its entirety. One such suitable polymeric acid that can be used as counter ion/dispersant for polythienothiophenes can have the following structure:

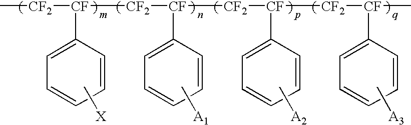

wherein at least two of m, n, p and q are integers greater than zero; A₁, A₂, and A₃ are selected from the group consisting of alkyls, halogens, CyF_{2y+1} where y is an integer greater than zero, O—R (where R is selected from the group consisting of alkyl, perfluoroalkyl and aryl moieties), CF═CF₂, CN, NO₂ and OH; and X is selected from the group consisting of SO₃H, PO₂H₂, PO₃H₂,CH₂PO₃H₂, COOH, OPO₃H₂, OSO₃H, OArSO₃H where Ar is an aromatic moiety, NR₃⁺ (where R is selected from the group consisting of alkyl, perfluoroalkyl and aryl moieties), and CH₂NR₃⁺ (where R is selected from the group consisting of alkyl, perfluoroalkyl and aryl moieties). The A₁, A₂, A₃ and X substituents may be located in the ortho, meta and/or para positions. The copolymer may also be binary, ternary or quaternary.

The compositions of the present invention are not limited to the homopolymeric structures above and may include hetereopolymeric or copolymeric structures. The copolymeric structures may be any combination of alternating copolymers(e.g., alternating A and B units), periodic copolymers (e.g., (A-B-A-B-B-A-A-A-A-B-B-B)n), random copolymers (e.g., random sequences of monomer A and B), statistical copolymers (e.g., polymer sequence obeying statistical rules) and/or block copolymers (e.g., two or more homopolymer subunits linked by covalent bonds). The copolymers may be branched or linked, provided the resultant copolymer maintains the properties of electrical conductivity. The copolymer structures may be formed from monomeric, oligomeric or polymeric compounds. For example, monomers suitable for use in the copolymer system may include monomers such as thiophene, substituted thiophenes, substituted thieno[3,4-b]thiophenes, dithieno[3,4-b:3′,4′-d]thiophene, pyrrole, bithiophene, substituted pyrroles, phenylene, substituted phenylenes, naphthalene, substituted naphthalenes, biphenyl and terphenyl, substituted terphenyl, phenylene vinylene and substituted phenylene vinylene.

In some cases, the dispersion can include at least one metal (e.g., at least one ion). Examples of metals that can be added or present in the dispersion comprise at least one member selected from the group consisting of Fe²⁺, Fe³⁺, K⁺, and Na⁺, and combinations thereof. The oxidizer:monomer molar ratio is usually about 0.05 to about 10, generally in the range of about 0.5 to about 5. (e.g., during the inventive polymerization steps). If desired, the amount of metal can be lowered or removed by exposing the dispersion to cationic and ionic exchange resins.

The monomer polymerization for the conductive polymer can be carried out in the presence of co-dispersing liquids which are normally miscible with water. Examples of suitable co-dispersing liquids comprise at least one member selected from the group consisting of ethers, alcohols, ethers, cyclic ethers, ketones, nitrites, sulfoxides, and combinations thereof. In one embodiment, the amount of co-dispersing liquid is less than about 30% by volume. In one aspect, the amount of co-dispersing liquid is less than about 60% by volume. In one aspect, the amount of co-dispersing liquid is between about 5% to about 50% by volume. In one aspect, the co-dispersing liquid comprises at least one alcohol. In one embodiment, the co-dispersing liquid comprises at least one member selected from the group of n-propanol, isopropanol, t-butanol, methanol, dimethylacetamide, dimethylformamide, N-methylpyrrolidone. The co-dispersing liquid can comprise an organic acid such as at least one member selected from the group consisting of p-toluenesulfonic acid, dodecylbenzenesulfonic acid, methanesulfonic acid, trifluoromethanesulfonic acid, camphorsulfonic acid, acetic acid, mixtures thereof and the like. Alternatively, the acid can comprise a water soluble polymeric acid such as poly(styrenesulfonic acid), poly(2-acrylamido-2-methyl-1-propanesulfonic acid), or the like, or a second colloid-forming acid, as described above. Combinations of acids can also be used.

The monomer polymerization can also be carried out in the presence of at least one ether containing polymer. The term “ether containing polymer” means a polymer comprising repeating units of the general formula (1)

-Q-R—

wherein Q is an oxygen atom or a sulfur atom, and R is a divalent radical of an aromatic or a heteroaromatic or an aliphatic compound, and R includes at least one sulfonic acid, phosphonic acid, boronic acid, or carboxylic acid, either in the acid form or in the neutralized form. Additional examples of suitable ether containing polymers are described in U.S. patent application Ser. No. 12/388,862, filed on Feb. 19, 2009; the disclosure of which is hereby incorporated by reference.

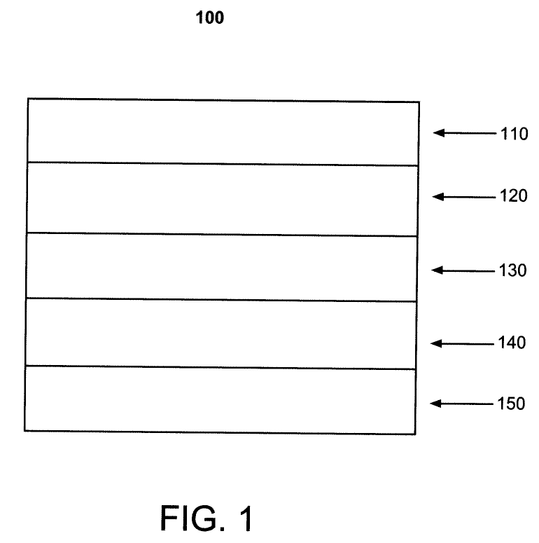

In another aspect, the invention relates to electronic devices comprising at least one electroactive layer (usually a semiconductor conjugated small molecule or polymer) positioned between two electrical contact layers, wherein at least one of the layers of the device includes the inventive hole injection layer. One embodiment of the present invention is illustrated by an OLED device, as shown in FIG. 1. Referring now to FIG. 1, FIG. 1 illustrates a device that comprises an anode layer 110, a hole injection layer (HIL) 120, an electroluminescent layer (EML) 130, and a cathode layer 150. Adjacent to the cathode layer 150 is an optional electron-injection/transport layer 140. Between the hole injection layer 120 and the cathode layer 150 (or optional electron injection/transport layer 140) is the electroluminescent layer 130. Alternatively, a layer of hole transport and /or electron blocking layer, commonly termed interlayer, can be inserted between the hole injection layer 120 and the electroluminescent layer 130. An example of the benefit of using polymeric interlayer in between HIL and EML is the improve the device lifetime as well as the device efficiency. Without wishing to be bound by any theory or explanation, it is believed that the polymer interlayer may prevent the exciton quenching at HIL interface by acting as an efficient exciton blocking layer and the recombination zone is confined near the interlayer/emitting layer interface. Since the polymer interlayer can be dissolved by the solvents of the EML thereby causing intermixing of the interlayer with the EML, it may be desirable to harden/corsslinking the layer by thermal annealing above the glass transition temperature (Tg).

The device may include a support or substrate (not shown) that can be adjacent to the anode layer 110 or the cathode layer 150. Typically, the support is adjacent the anode layer 110. The support can be flexible or rigid, organic or inorganic. Generally, glass or flexible organic films are used as a support (e.g., a flexible organic film comprising poly(ethylene terephthalate), poly(ethylene naphthalene-2.6,-dicarboxylate), and polysulfone). The anode layer 110 comprises an electrode that is more efficient for injecting holes compared to the cathode layer 150. The anode can comprise materials containing a metal, mixed metal, alloy, metal oxide or mixed oxide. Suitable materials comprise at last one member selected from the group consisting of mixed oxides of the Group 2 elements (e.g., Be, Mg, Ca, Sr, Ba, Ra), the Group 11 elements, the elements in Groups 4, 5, and 6, and the Group 8-10 transition elements (The IUPAC number system is used throughout, where the groups from the Periodic Table are numbered from left to right as 1-18 [CRC Handbook of Chemistry and Physics, 81^{st} Edition, 2000]). If the anode layer 110 is light transmitting, then mixed oxides of Groups 12; 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, comprise at least one member selected from the group consisting of indium-tin-oxide (“ITO”), aluminum-tin-oxide, doped zinc oxide, gold, silver, copper, and nickel. The anode may also comprise a conductive organic material such as polyaniline, polythiophene or polypyrrole.

The anode layer 110 may be formed by any suitable process such as chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include RF magnetron sputtering and inductively-coupled plasma physical vapor deposition (“IMP-PVD”). These deposition techniques are well known within the semiconductor fabrication arts.

The anode layer 110 may be patterned during a lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used. When the electronic devices are located within an array, the anode layer 110 typically is formed into substantially parallel strips having lengths that extend in substantially the same direction.

The hole injection layer 120 is usually cast onto substrates using a variety of techniques well-known to those skilled in the art. Typical casting techniques include, for example, solution casting, drop casting, curtain casting, spin-coating, screen printing, inkjet printing, among others When the hole injection layer is applied by spin coating, the viscosity and solid contents of the dispersion, and the spin rate can be employed to adjust the resultant film thickness. Films applied by spin coating-are generally continuous and without pattern. Alternatively, the hole injection layer can be patterned using a number of depositing processes, such as ink jet-printing such as described in U.S. Pat. No. 6,087,196; hereby incorporated by reference.

The electroluminescent (EL) layer 130 may typically be a conjugated polymer, such as poly(paraphenylenevinylene), abbreviated as PPV, polyfluorene, spiropolyfluorene or other EL polymer material. The EL layer can also comprise relatively small molecules fluorescent or phosphorescent dye such as 8-hydroxquinoline aluminum (Alq.₃) and tris(2-(4-tolyl)phenylpyridine) Iridium (III), a dendrimer, a blend that contains the above-mentioned materials, and combinations. The EL layer can also comprise inorganic quantum dots or blends of semiconducting organic material with inorganic quantum dots. The particular material chosen may depend on the specific application, potentials used during operation, or other factors. The EL layer 130 containing the electroluminescent organic material can be applied from solutions by any conventional technique, including spin-coating, casting, and printing. The EL organic materials can be applied directly by vapor deposition processes, depending upon the nature of the materials. In another embodiment, an EL polymer precursor can be applied and then converted to the polymer, typically by heat or other source of external energy (e.g., visible light or UV radiation).

Optional layer 140 can function both to facilitate electron injection/transport, and can also serve as a confinement layer to prevent quenching reactions at layer interfaces. That is, layer 140 may promote electron mobility and reduce the likelihood of a quenching reaction that can occur when layers 130 and 150 are in direct contact. Examples of materials for optional layer 140 comprise at least one member selected from the group consisting of metal-chelated oxinoid compounds (e.g., Alq..₃ or the like); phenanthroline-based compounds (e.g., 2,9-dimethyl-4,7-diphenyl-1,10-phenanthroline (“DDPA”), 4,7-diphenyl-1,10-phenanthroline (“DPA”), or the like); azole compounds (e.g., 2-(4-biphenylyl)-5-(4-t-butylphenyl)-1,3,4-oxadiazole (“PBD” or the like), 3-(4-biphenylyl)-4-phenyl-5-(4-t-butylphenyl)-1,2,4-triazole (“TAZ” or the like); other similar compounds; or any one or more combinations thereof. Alternatively, optional layer 140 may be inorganic and comprise BaO, CaO, LiF, CsF, NaCl, Li₂O, mixtures thereof, among others.

The cathode layer 150 comprises an electrode that is particularly efficient for injecting electrons or negative charge carriers. The cathode layer 150 can comprise any suitable metal or nonmetal having a lower work function than the first electrical contact layer (in this case, the anode layer 110). As used herein, the term “lower work function” is intended to mean a material having a work function no greater than about 4.4 eV. As used herein, “higher work function” is intended to mean a material having a work function of at least approximately 4.4 eV.

Materials for the cathode layer can be selected from alkali metals of Group 1 (e.g., Li, Na, K, Rb, Cs,), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 150 comprise at least one member selected from the group consisting of calcium, barium, lithium, cerium, cesium, europium, rubidium, yttrium, magnesium, samarium, and alloys and combinations thereof. When a reactive low work function metal such as Ca, Ba or Li is used, an overcoat of a more inert metal, such as silver or aluminum, can be used to protect the reactive metal and lower the cathode resistance.

The cathode layer 150 is usually formed by a chemical or physical vapor deposition process. In general, the cathode layer will be patterned, as discussed above in reference to the anode layer 110. If the device lies within an array, the cathode layer 150 may be patterned into substantially parallel strips, where the lengths of the cathode layer strips extend in substantially the same direction and substantially perpendicular to the lengths of the anode layer strips. Electronic elements called pixels are formed at the cross points (where an anode layer strip intersects a cathode layer strip when the array is seen from a plan or top view). For top emitting devices, a very thin layer of low work function metal such as Ca and Ba combined with a thicker layer transparent conductor such as ITO can be used as transparent cathode. Top emitting devices are beneficial in active matrix display because larger aperture ratio can be realized. Examples of such devices are described in “Integration of Organic LED's and Amorphous Si TFT's onto Flexible and Lightweight Metal Foil Substrates”; by C. C. Wu et al; IEEE Electron Device Letters, Vol. 18, No. 12, December 1997, hereby incorporated by reference.

In other embodiments, additional layer(s) may be present within organic electronic devices. For example, a layer (not shown) between the hole injection layer 120 and the EL layer 130 may facilitate positive charge transport, energy-level matching of the layers, function as a protective layer, among other functions. Similarly, additional layers (not shown) between the EL layer 130 and the cathode layer 150 may facilitate negative charge transport, energy-level matching between the layers, function as a protective layer, among other functions. Layers that are known in the art can be also be included. In addition, any of the above-described layers can be made of two or more layers. Alternatively, some or all of inorganic anode layer 110, the hole injection layer 120, the EL layer 130, and cathode layer 150, may be surface treated to increase charge carrier transport efficiency. The choice of materials for each of the component layers may be determined by balancing the goals of providing a device with high device efficiency and longer device lifetime with the cost of manufacturing, manufacturing complexities, or potentially other factors

The different layers may have any suitable thickness. Inorganic anode layer 110 is usually no greater than approximately 500 nm, for example, approximately 10-200 nm; hole injection layer 120, is usually no greater than approximately 300 nm, for example, approximately 30-200 nm; EL layer 130, is usually no greater than approximately 1000 nm, for example, approximately 30-500 nm; optional layer 140 is usually no greater than approximately 100 nm, for example, approximately 20-80 nm; and cathode layer 150 is usually no greater than approximately 300 nm, for example, approximately 1-150 nm. If the anode layer 110 or the cathode layer 150 needs to transmit at least some light, the thickness of such layer may not exceed approximately 150 nm.

Depending upon the application of the electronic device, the EL layer 130 can be a light-emitting layer that is activated by signal (such as in a light-emitting diode) or a layer of material that responds to radiant energy and generates a signal with or without an applied potential (such as detectors or photovoltaic cells). The light-emitting materials may be dispersed in a matrix of another material, with or without additives, and may form a layer alone. The EL layer 130 generally has a thickness in the range of approximately 30-500 nm.

Examples of other organic electronic devices that may benefit from having one or more layers comprising the aqueous dispersion comprising polythienothiophene made with polymeric acid colloids comprise: (1) devices that convert electrical energy into radiation (e.g., a light-emitting diode, light emitting diode display, or diode laser), (2) devices that detect signals through electronics processes (e.g., photodetectors (e.g., photoconductive cells, photoresistors, photoswitches, phototransistors, phototubes), IR detectors), (3) devices that convert radiation into electrical energy, (e.g., a photovoltaic device or solar cell), and (4) devices that include one or more electronic components that include one or more organic semi-conductor layers (e.g., a transistor or diode).

Organic light emitting diodes (OLEDs) inject electrons and holes from the cathode 150 and anode 110 layers, respectively, into the EL layer 130, and form negative and positively charged polarons in the polymer. These polarons migrate under the influence of the applied electric field, forming an exciton with an oppositely charged polarons and subsequently undergoing radiative recombination. A sufficient potential difference between the anode and cathode, usually less than approximately 12 volts, and in many instances no greater than approximately 5 volts, may be applied to the device. The actual potential difference may depend on the use of the device in a larger electronic component. In many embodiments, the anode layer 110 is biased to a positive voltage and the cathode layer 150 is at substantially ground potential or zero volts during the operation of the electronic device. A battery or other power source(s), not shown, may be electrically connected to the electronic device as part of a circuit.

Additives useful in the dispersions of the instant invention can be organic liquids commonly characterized as solvents/humectants. These include, but are not limited to
(1) alcohols, such as methyl alcohol, ethyl alcohol, n-propyl alcohol, isopropyl alcohol, n-butyl alcohol, sec-butyl alcohol, t-butyl alcohol, iso-butyl alcohol, furfuryl alcohol, and tetrahydrofurfuryl alcohol;
(2) polyhydric alcohols, such as ethylene glycol, diethylene glycol, triethylene glycol, tetraethylene glycol, propylene glycol, polyethylene glycol, glycerol, 2-methyl-2,4-pentanediol, 1,2,6-hexanetriol, 2-ethyl-2-hydroxymethyl-1,3-propanediol, 1,5 pentanediol, 1,2-hexanediol, and thioglycol;
(3) lower mono- and di-alkyl ethers derived from the polyhydric alcohols;
(4) nitrogen-containing compounds such as 2-pyrrolidone, N-methyl-2-pyrrolidone, and 1,3-dimethyl-2-imidazolidinone; and
(5) sulfur-containing compounds such as 2,2′-thiodiethanol, dimethyl sulfoxide and tetramethylene sulfone,
6) Ketones, ethers and esters.

Examples of polyhydric alcohols suitable for use a film forming additive include, but are not limited to, ethylene glycol, diethylene glycol(DEG), triethylene glycol, propylene glycol, tetraethylene glycol, polyethylene glycol, glycerol, 2-methyl-2,4-pentanediol, 2-ethyl-2-hydroxymethyl-1,3-propanediol(EH MP), 1,5 pentanediol, 1,2-hexanediol, 1,2,6-hexanetriol and thioglycol. Examples of lower alkyl mono- or di-ethers derived from polyhydric alcohols include, but are not limited to, ethylene glycol mono-methyl or mono-ethyl ether, diethylene glycol mono-methyl or mono-ethyl ether, propylene glycol mono-methyl, mono-ethyl and propyl ether, triethylene glycol mono-methyl, mono-ethyl or mono-butyl ether (TEGMBE), diethylene glycol di-methyl or di-ethyl ether, poly(ethylene glycol) monobutyl ether (PEGMBE), diethylene glycol monobutylether(DEGMBE) and propylene glycol methyl ether acetate. Commercial examples of such compounds include Dow P-series and E-series glycol ethers in the Carbitol™ and Dowanol® product family, available from Dow Chemical Company, Midland, Mich.

Examples of ketones or ketoalcohols suitable for use a film forming additive include, but are not limited to, acetone, methyl ethyl ketone and diacetone alcohol. Examples of ethers include, but not limited to tetrahydrofuran and dioxane, and examples of esters include, but not limited to ethyl lactate, ethylene carbonate and propylene carbonate.

Film forming additives useful for the current invention may also include a surfactant. The surfactants may be anionic, cationic, amphoteric or nonionic and used at levels of 0.005 to 2% of the ink composition. Examples of useful surfactants include, but not limited to, from those disclosed in U.S. Pat. Nos. 5,324,349; 4,156,616 and 5,279,654 as well as many other surfactants known in the printing and coating art. Commercial surfactants include the Surfynos™, Dynol™ from Air Products; the Zonys™ from DuPont and the Fluorads™ (now Novec™) from 3M. Examples of silicon surfactants are available from BYK-Chemie as BYK surfactants, and from Crompton Corp, as Silwet™ surfactants. Commercially available fluorinated surfactants can be the Zonyls™ from DuPont and the Fluorads™ (now Novec™) from 3M, they can be used alone or in combination with other surfactants.

Combinations of film forming additives may also be utilized. Film forming additives can be selected (viscosity modifier, surface tension modifier) in order to provide desirable film forming properties. This can permit dispersions of the instant invention to be employed by electronic device manufacturers in a broad range of applications, including light emitting display, solid state lighting, photovoltaic cells and thin fim transistors.

In some aspects of the invention, the wt % of additive added in the dispersion is 95% of the maximum solubility. If desired, the wt % of additive added in the dispersion is 90% of the maximum solubility, or the wt % of additive added in the ink is 80% of the maximum solubility.

The device formed using the dispersion of the present disclosure includes a conductive polymeric film and a conductive polymeric film disposed on a substrate. The films of this invention are typically applied to an article. The film may be deposited utilizing any suitable technique known in the art for applying polymer films. The film application or fabrication methods include but are not limited to spin coating, doctor blade coating, ink jet printing, screen printing, thermal transfer printing, microcontact printing or digital printing. Thickness of the film can range from 2 nm to 1000 nm, or from 20 nm to 500 nm, or from 50 nm to 200 nm. After the film is deposited from the dispersion, the film may be dried in air or heated at a temperature from 50° C. to 250° C., or, if desired, from 100° C. to 200° C. to remove the residual solvent, or other volatiles and, in some applications, in an inert atmosphere.

In certain aspects of the invention, the film is spun-on a substrate surface and dried. The conductive film within the device can includes a conductivity of from about 10⁻⁶ S/cm to about 300 S/cm. “Drying” and variations thereof include air-drying, forced air drying, drying at elevated temperatures and annealing of the polymer film. “Annealing”, “Annealed” and variations thereof include heating of a solid material at a sufficient temperature for a sufficient time, where a portion or most of solvent and/or water therein volatilizes.

In accordance with other aspects, the present disclosure relates to organic electronic devices, including electroluminescent devices, comprising hole injection layer of the inventive compositions. In addition, the present invention permits fabricating bi-layered devices having acceptable lifetime performance. By “lifetime” it is meant the length of time taken for an initial brightness of a continuously operating device (e.g., a PLED) to decrease to a ratio of the initial brightness that is acceptable for the targeted application (e.g., 50% of the initial brightness).

It is known that wetting is the contact between a fluid and a surface. When a liquid has a high surface tension (strong internal bonds), it tends to form a droplet on the surface. Whereas a liquid with low surface tension tends to spread out over a greater area (bonding to the surface). On the other hand, if a solid surface has high surface energy (or surface tension), a drop will spread, or wet, the surface. If the solid surface has low surface energy, a droplet will form. This phenomenon is a result of the minimization of interfacial energy. The primary measurement to determine wettability is a contact angle measurement. This measures the angle between the surfaces of a liquid droplet on the solid surface.

In the field of using water based conductive polymer dispersions as the hole injection layer in an OLED device, it is known that the nature of the dispersant can have a significant impact on device performance including efficiency and lifetime. For example, compared to Poly(StyreneSulfonate) PSSA, when a highly fluorinated polymeric dispersant such as Nafion® fluoropolymer is used, the device lifetime can be significantly increase (>5× normally). However, one key deficiency of this group of dispersant can be the hydrophobic nature of the material which leads to low surface energy (high contact angle) of the dried film formed by the dispersion. [0078] Surface energy of film can be controlled by the chemical structure of the surface. In OLED devices, films are formed by solution processing steps which involves depositing or laying down a dispersion containing polymer particles and a carrier media (water or solvent) followed by the carrier medium drying off or volatilizing from the film surface leaving the polymer film. As a result, when there are competing chemical species in the dispersion, the final surface energy is determined by the distribution of surface chemical species produced at the end of the film drying step (e.g., a dynamic “locked in” film state).

In accordance with one aspect of this invention, it has been discovered that a wide range of hydrophilic polymeric species can be added to the highly fluorinated polymeric dispersant containing conductive polymers to increase the film surface energy (i.e., reduce the wetting angle), and thus permitting a wider range of materials to be used in the deposition of the subsequent layers. These materials when used in junction with the inventive wet on wet process, can be used to make devices with improved life time and efficiency, yet wettable for the next layer material deposition.

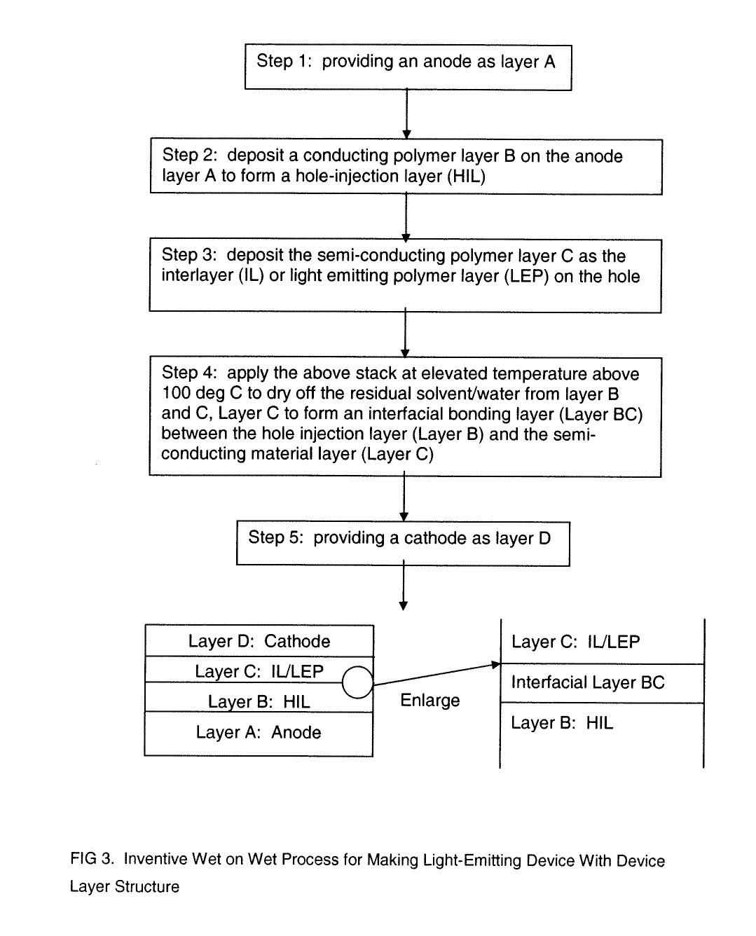

Without wishing to be bound by any theory or explanation, it is believed that the interfacial properties between the HIL and LEP can be quite different when wet on wet process is used to form the conducting polymer layer and subsequent semi-conducting polymer layer. As illustrated in FIG. 3, a wet on wet process permits forming an interfacial bonding layer (Layer BC) between the hole injection layer (Layer B) and the semi-conducting material layer (Layer C). This layer promotes better adhesion between the adjacent layers thereby leading to improved device performance. This is an especially useful feature when materials used in the layers such as semi-conducting layer comprise poor adhesion components.

Certain aspects of this invention are illustrated by the following Examples. These Examples shall not limit the scope of the appended claims.

### EXAMPLES

### Conductive polymer dispersion D1 (poly(thieno[3,4-b]thiophene (PTT)/NAFION® 1:18)

1700 grams of deionized water were added to a 3 L jacketed reactor. 600 grams of a 12% NAFION® dispersion in water (Dupont Co.) were added to the reactor and mixed for 5 minutes with an overhead stirrer. The jacketed flask was adjusted to maintain a 22° C. reaction temperature. 4 grams (28.6 mmol) of thieno[3,4-b]thiophene was separately co-fed into the reactor with 17.7 grams (34.2 mmole) of Fe₂(SO4)₃*H₂O dissolved in 350 grams of deionized water. The reaction mass turned from light green to emerald green to dark blue within 20 minutes. Polymerization was allowed to proceed for 4 hours after the introduction of monomer and oxidant. The resulting dispersion was then purified by adding the contents of the reactor to a 4 L Nalgene® bottle containing 94.0 grams of Amberlite® IR-120 cation exchange resin (Sigma-Aldrich Chemical Co) and 94.0 grams of Lewatit® MP-62 anion exchange resin (Fluka, Sigma-Aldrich Chemical Co), resulting in an opaque dark blue aqueous poly(thieno[3,4-b]thiophene)/NAFION® dispersion. The dispersion was filtered sequentially through 5, 0.65 and 0.45 micron pore size filters. The dispersion was analyzed for residual metal ions by ICP-MS with the following ions being detected: Al (<1 ppm); Ba (<1 ppm); Ca (<20 ppm); Cr (<1 ppm), Fe (37 ppm); Mg (<1 ppm); Mn (<1 ppm); Ni (<1 ppm); Zn (<1 ppm); Na (<=6 ppm); K (<1 ppm). The final dispersion has a solid content of 3%, NAFION to TT weight ratio of 18:1, Viscosity of 2.1 mPa·s and pH of 2.4.

Viscosity of the dispersion was measured using an ARES controlled-strain rheometer (TA Instruments, New Castle, Del., formerly Rheometric Scientific). Temperature was controlled at 25° C. using a circulating water bath. The atmosphere was saturated with water vapor to minimize water evaporation during testing. A Couette geometry was used; both bob and cup were constructed out of titanium. The bob was 3 mm in diameter and 33.3 mm in length; the diameter of the cup was 34 mm. Approximately 10 ml of sample was used per experiment. After sample loading, the sample was subjected to a 5 min preshear at 100 s⁻¹ for removing the effects of loading history. After a 15 minute delay, viscosities were measured at shear rates ranging from 1 to 200 s⁻¹.

### Conductive Polymer Dispersion D2 (PTT/NAFION 1:12)

1700 grams of deionized water were added to a 3 L jacketed reactor. 600 grams of a 12% NAFION® dispersion in water (Dupont Co.) were added to the reactor and mixed for 5 minutes with an overhead stirrer. The jacketed flask was adjusted to maintain a 22° C. reaction temperature. 6 grams(42.9 mmol) of thieno[3,4-b]thiophene were separately co-fed into the reactor with 26.6 grams (51.4 mmole) of Fe₂(SO4)₃*H2O dissolved in 525 grams of deionized water. The reaction mass turned from light green to emerald green to dark blue within 20 minutes. Polymerization was allowed to proceed for 4 hours after the introduction of monomer and oxidant. The resulting dispersion was then purified by adding the contents of the reactor to a 4L Nalgene® bottle containing 141 grams of Amberlite® IR-120 cation exchange resin (Sigma-Aldrich Chemical Co) and 141 grams of Lewatit® MP-62 anion exchange resin (Fluka, Sigma-Aldrich Chemical Co), resulting in an opaque dark blue aqueous poly(thieno[3,4-b]thiophene)/NAFION® dispersion. The dispersion was filtered sequentially through 5, 0.65 and 0.45 micron pore size filters. The dispersion was analyzed for residual metal ions by ICP-MS with the following ions being detected: Al (<1 ppm); Ba (<1 ppm); Ca (<20 ppm); Cr (<1 ppm), Fe (29 ppm); Mg (<1 ppm); Mn (<1 ppm); Ni (<1 ppm); Zn (<1 ppm); Na (<=6 ppm); K (<1 ppm). The final dispersion has a solid content of 3%, NAFION to TT weight ratio of 12:1, Viscosity of 2.4 mPa·s and pH of 2.5.

### Example A

### Device Performance Using the Inventive Wet on Wet Process

### Conductive Polymer Ink Ink-A1

To prepare conductive polymer ink INK-A1, 7.5 g conductive polymer dispersion D1 (3% solid by weight), 2.5 g of propylene glycol propyl ether (Aldrich Chemical Company, Inc) were mixed so that the final weight of the ink was 10.0 g. The final ink contained 2.3 wt % conductive polymer and 25 wt % propylene glycol propyl ether.

### Conductive Polymer Ink Ink-A2

To prepare conductive polymer ink INK-A2, poly(styrene sulfonic acid) PSSA of average molecular weight of 75K was first diluted to 3wt % from its stock solution. Then 19.3 g conductive polymer dispersion D2 (3% solid by weight) and 0.7 g of PSSA (3 wt %) were mixed together so that the final weight of the ink was 20.0 g. The final ink contained total of 3 wt % total solid with 4 wt % of PSSA.

### Light-Emitting Device I-D1

Organic light-emitting device I-D1 is carried out as follows: patterned indium tin oxide coated glass substrate of 10-15 Ω/square (from Colorado Concept Coatings LLC) was used as the anode. The ITO substrates were cleaned by a combination of de-ionized water, detergent, methanol and acetone. Then the ITO substrate was treated with oxygen plasma in an SPI Prep II plasma etcher for about 10 min. After that, the ITO substrate was spin coated with conductive polymer ink Ink-A1 at 200 rpm spin speed for 5 min on a Laurell Model WS-400-N6PP spinner. Ink-A1 was filtered with a 0.45 micron PVDF filter before spin coating. A uniform film of was obtained with a film thickness of about 70 nm as measured by a KLA Tencor P-15 Profiler. Then, a layer of about 80-nm-thick green light emitting polymer Lumation 1304 from CDT was spin coated from toluene solution. The samples were then baked at 130° C. for 20 min on a hotplate under N₂ protection. The sample was then transferred into the chamber of a vacuum evaporator, which was located inside an argon atmosphere glove box. A layer of Ba was vacuum deposited followed by a layer of Ag. The devices were then encapsulated with glass cover lid and UV curable epoxy in the argon glove box. The active area of the device was about 6.2 mm². The LED device was then moved out of the glove box for testing in air at room temperature.

### Light-Emitting Device C-D1 (Control)

Light-emitting device C-D1 was made similar to device I-D1, except that after the conductive polymer ink Ink-A1 was spin coated on ITO, the film on ITO substrate was annealed at 180° C. for 15 min under the Nitrogen environment. The annealed HIL film on ITO was then transferred to the glove box for the deposition of light emitting polymer as described in I-D1.

### Light-Emitting Device I-D2

Light -emitting device l-D2 was made similar to device I-D1, except that conductive polymer dispersion D2 instead of conductive polymer Ink-A1 was spin coated on ITO using 1000 rpm for 1 min. After the deposition of green light emitting polymer, the entire the film stack was then baked at 130° C. for 40 min on a hotplate under N₂ protection.

### Light-Emitting Device C-D2 (Control)

Light-emitting device C-D2 was made similar to device I-D2, except that after the conductive polymer dispersion D2 was spin coated on ITO, the film on ITO substrate was annealed at 160° C. for 15 min under the Nitrogen environment. The annealed HIL film on ITO was then transferred to the glove box for the deposition of light emitting polymer as described in I-D2.

### Light-Emitting Device I-D3

Light-emitting device I-D3 was made similar to device I-D1, except that conductive polymer dispersion D1 instead of conductive polymer Ink-A1 was spin coated on ITO at a spin speed of 1000 rpm instead of 2000 rpm.

### Light-Emitting Device C-D3 (Control)

Light -emitting device C-D3 was made similar to device I-D3, except that after the conductive polymer dispersion D2 was spin coated on ITO, the film on ITO substrate was annealed at 180° C. for 15 min under the Nitrogen environment. The annealed HIL film on ITO was then transferred to the glove box for the deposition of light emitting polymer as described in I-D3.

### Light-Emitting Device I-D4

Light-emitting device I-D4 was made similar to device I-D1, except that conductive polymer ink INK-A2 instead of conductive polymer Ink-A1 was spin coated on ITO at a spin speed of 1000 rpm instead of 2000 rpm.

### Light-Emitting Device C-D4 (Control)

Light -emitting device C-D4 was made similar to device I-D4, except that after the conductive polymer ink-A2 was spin coated on ITO, the film on ITO substrate was annealed at 180° C. for 15 min under the Nitrogen environment. The annealed HIL film on ITO was then transferred to the glove box for the deposition of light emitting polymer as described in I-D4.

### Device Testing

Current-voltage characteristics of the light emitting devices were measured on a Keithley 2400 SourceMeter. Electroluminescence (EL) spectrum of the device was measured using an Oriel InstaSpec IV CCD camera. The power of EL emission was measured using a Newport 2835-C multi-function optical meter in conjunction with a calibrated Si photodiode. Brightness was calculated using the EL forward output power and the EL spectrum of the device, assuming Lambertian distribution of the EL emission, and verified with a Photo Research PR650 calorimeter. The lifetime of PLED devices was measured on an Elipse™ PLED Lifetime Tester (from Cambridge Display Technology) under constant current driving condition at room temperature. The driving current was set according to the current density needed to achieve the initial brightness measured using the Si photodiode. For this set of experiments, we selected 5000 nits as the initial device brightness and defined the life time of the device as the time takes for the brightness to reach 50% of the initial value. Since multiple devices were made using the same ink composition and same device making process, the maximum current efficiency from IVB measurement and the life time of the device from lifetime tester were reported as a range. The turn on voltage V_on is measured as the voltage at which the device starts to light up with visible brightness. The leakage current is defined as the current density at the 0.5 of the turn on voltage (V_on).

TABLE A
Device performance and process condition comparison for Example A

| | | Total | Processing | Turn | | | Max. |
|---|---|---|---|---|---|---|---|
| Light- | | Annealing | time | on | Leakage | Life | Current |
| Emitting | Deposition | Time | Reduction | Voltage | Current | time | Efficiency |
| Device | Process | (mins) | (%) | (V) | (mA/cm²) | (hrs) | (Cd/A) |
| I-D1 | Wet on | 20 | 43% | 2.5-2.7 | 3.7-4 × 10⁻⁵ | 310-400 | 13.5-15.0 |
| | wet | | | | | | |
| C-D1 | Wet on | 35 | 0% | 2.5 | 0.6-1 × 10⁻³ | 330-400 | 11.1-14.8 |
| | Dry | | | | | | |
| I-D2 | Wet on | 40 | 27% | 2.5 | 0.05 | N/A | 8.4-9.0 |
| | wet | | | | | | |
| C-D2 | Wet on | 55 | 0% | 2.5 | 0.2 | N/A | 8.8-9.0 |
| | Dry | | | | | | |
| I-D3 | Wet on | 20 | 43% | 2.5 | 5-9 × 10⁻³ | 350-370 | 12.9-13.5 |
| | wet | | | | | | |
| C-D3 | Wet on | 35 | 0% | 2.5-2.6 | 0.4-1.1 × 10⁻² | 270-360 | 10.6-14.3 |
| | Dry | | | | | | |
| I-D4 | Wet on | 20 | 43% | 2.5 | 2.1-2.4 × 10⁻³ | 170-240 | 8.1-12.8 |
| | wet | | | | | | |
| C-D4 | Wet on | 35 | 0% | 2.5 | 2.7-3.2 × 10⁻² | 320-336 | 8.3-11.9 |
| | Dry | | | | | | |

The data in Table A clearly demonstrated that compared with devices made from the conventional wet on dry process (control devices), the devices made by the present inventive wet on wet process has showed overall improvement in the combined features of significant reduction in processing time (thus shorter TAC time), lower leakage current while maintaining a useful life time and efficiency performance.

### Example B

### Conductive Polymer Ink with Improved Film Metting Properties Suitable for Present Inventive Wet on Wet Process

### Conductive polymer Ink I-B1

To prepare conductive polymer ink I-B1, poly(styrene sulfonic acid) PSSA of average molecular weight of 75K was first diluted to 3 wt % from its stock solution. Then 19.3 g conductive polymer dispersion D2 (3% solid by weight) and 0.7 g of PSSA (3 wt %) were mixed together so that the final weight of the ink was 20.0 g. The final ink contained total of 3 wt % total solid with 4 wt % of PSSA.

### Conductive Polymer Ink I-B2

Conductive polymer ink I-B2 was prepared similar to I-B1, except that the amount of PSSA added is calculated so that the final ink contained total of 3 wt % total solid with 5 wt % of PSSA.

### Conductive Polymer Ink I-B3

Conductive polymer ink I-B3 was prepared similar to I-B1, except that the PSSA used has a MW of 1000K instead of 75K and the amount of PSSA added is calculated so that the final ink contained total of 3 wt % total solid with 10 wt % of PSSA.

### Conductive Polymer Ink I-B4

Conductive polymer ink I-B4 was prepared similar to I-B1, except that the PSSA used has a MW of 1000K instead of 75K and the amount of PSSA is added so that the final ink contained total of 3 wt % total solid with 25 wt % of PSSA. Further analysis from the ion content of the PSSA used in this ink contains significant higher level of metal ions as compared to PSSA used in the rest of the examples.

### Conductive Polymer Ink I-B5

Conductive polymer ink I-B5 was prepared similar to I-B1, except that the PSSA used has a MW of 200K instead of 75K and the amount of PSSA is added so that the final ink contained total of 3 wt % total solid with 50 wt % of PSSA. In addition, the conductive polymer dispersion used is D1 instead of D2.

### Conductive Polymer Ink I-B6

Conductive polymer ink I-B6 was prepared similar to I-B1, except that additional amount of propylene glycol propyl ether (Aldrich Chemical Company, Inc) were mixed into the dispersion so that the final ink contained total of 3 wt % total solid with 4 wt % of PSSA and 5% propylene glycol propyl ether

### Conductive Polymer Ink I-B7

Conductive polymer ink I-B7 was prepared similar to conductive polymer dispersion D1, except that ionomer dispersant present in the reactor before the addition of TT monomer contains 7 wt % of PSSA and 93 wt % of Nafion. The final ink contained total of 3 wt % total solid with 7 wt % of PSSA which is added during the polymerization process

### Conductive Polymer Ink I-B8

Conductive polymer ink I-B8 was prepared similar to conductive polymer ink I-B7, except that the amount of PSSA added before the addition of TT monomer contains 14 wt % of PSSA and 86 wt % of Nafion. The final ink contained total of 3 wt % total solid with 14 wt % of PSSA which is added during the polymerization process

### Conductive Polymer Ink I-B9

Conductive polymer ink I-B9 was prepared similar to conductive polymer ink I-B7, except that the amount of PSSA added before the addition of TT monomer contains 50 wt % of PSSA and 50 wt % of Nafion. The final ink contained total of 3 wt % total solid with 50 wt % of PSSA which is added during the polymerization process.

### Conductive Polymer Ink I-B10

Conductive polymer ink I-B10 is the commercial available conductive polymer Baytron CH8000 (a PEDOT/PSSA dispersion) which is available from H. C Starck.

Device fabrication and testing were carried out as follows: the light emitting devices were fabricated on patterned indium tin oxide coated glass substrate of 10-15 Ω/square (from Colorado Concept Coatings LLC). The ITO substrates were cleaned by a combination of de-ionized water, detergent, methanol and acetone. Then the ITO substrate was treated with oxygen plasma in an SPI Prep II plasma etcher for about 10 min. After that, the ITO substrate was spin coated with conductive polymer inks at selected spin speed in order to obtain a film thickness of around 70-100 nm. The spin length is programmed to be 1 min on a Laurell Model WS-400-N6PP spinner. All conductive poymer inks were filtered with a 0.45 micron PVDF filter before spin coating. A uniform film of was obtained. The ITO substrates were then annealed at 180 to 200° C. for 15 min. After the annealing, a layer of about 80-nm-thick green light emitting polymer was spin coated from toluene solution. The samples were then baked at 130° C. for 20 min on a hotplate under N2 protection. The samples were then transferred into the chamber of a vacuum evaporator, which was located inside an argon atmosphere glove box. A layer of Ba was vacuum deposited followed by a layer of Ag. The devices were then encapsulated with glass cover lid and UV curable epoxy in the argon glove box. The active area of the device was about 6.2 mm². The LED device was then moved out of the glove box for testing in air at room temperature. Thickness was measured on a KLA Tencor P-15 Profiler. Current-voltage characteristics were measured on a Keithley 2400 SourceMeter. Electroluminescence (EL) spectrum of the device was measured using an Oriel InstaSpec IV CCD camera. The power of EL emission was measured using a Newport 2835-C multi-function optical meter in conjunction with a calibrated Si photodiode. Brightness was calculated using the EL forward output power and the EL spectrum of the device, assuming Lambertian distribution of the EL emission, and verified with a Photo Research PR650 colorimeter. The lifetime of PLED devices was measured on an Elipse™ PLED Lifetime Tester (from Cambridge Display Technology) under constant current driving condition at room temperature. The driving current was set according to the current density needed to achieve the initial brightness measured using the Si photodiode. For this set of experiments, we selected 5000 nits as the initial device brightness and defined the life time of the device as the time takes for the brightness to reach 50% of the initial value. Since multiple devices were made using the same ink composition, the maximum current efficiency from IVB measurement and the life time of the device from lifetime tester were reported as a range in Table B1.

In order to characterize the film wetting property, inks were deposited onto substrates (e.g. 1″×1″ ITO/Glass supplied by Colorado Concept Coatings LLC). For the current example, spin coating method was used. The specific spin speed was selected in order to achieve the film thickness between 50-100 nm. Kruss Drop Shape Analysis System model DSA10 MK2 was used to obtained the contact angle of a liquid (such as water or organic solvent) drop onto the film under study. The equipment records the drop spreading over a specified time period (60 seconds). The drop shape analysis software calculates contact angle using a circle fitting method over this 60 second period. The data shown in Table B1 is collected using water as the liquid drop. When unannealed film represent the film obtained after deposited by the spin coating method and left in ambient condition for 2 hrs. The annealed films have been thermally treated on a hot plate of 180° C. for 15 mins in air.

TABLE B1
Conductive polymer inks with improved film wetting properties
suitable for present inventive wet on wet process

| | | Contact | | |
|---|---|---|---|---|
| Conductive | Contact angle | angle after | | Max. Current |
| Polymer | before annealing | annealing | Life time | Efficiency |
| Inks | (deg) | (deg) | (hrs) | (Cd/A) |
| I-B1 | 22-23 | 77-81 | 350-370 | 12.9-13.5 |
| I-B2 | 6-7 | 86-87 | N/A | N/A |
| I-B3 | 15-16 | 85-86 | 248-265 | 10-12.3 |
| I-B4 | 13-14 | 25-29 | 103-107 | 12.5-13 |
| I-B5 | 7-8 | 95-96 | N/A | N/A |
| I-B6 | 15-16 | 76-77 | N/A | N/A |
| I-B7 | 3-7 | 77-83 | 325 | N/A |
| I-B8 | 14-15 | 76-80 | 280 | N/A |
| I-B9 | 8-10 | 41-45 | 220 | N/A |
| I-B10 | 10 | 22-25 | 20-50 | 8.3-8.5 |
| D1 | 80-82 | 81-82 | 450-500 | 11.0-11.3 |
| D2 | 80-82 | 81-82 | 450-500 | 11.0-11.3 |

To further demonstrate the conductive polymer film property, film surface energy was determined by using the two component Flowkes theory model. Flowkes' theory assumes that the adhesive energy between a solid and a liquid can be separated into interactions between the dispersive components of the two phases and interactions between the non-dispersive(polar) components of the two phases. The dispersive component of the surface energy σₛ^{D} was determined by measuring the film contact angle with a liquid which has only a dispersive component, such as Diiodomethane (σ_{L}=σ_{L}^{D}=50.8 mN/m). Afterwards, the film contact angle with the second liquid which has both a dispersive component and a non-dispersive (polar) component e.g. water (σ_{L}^{P}=46.4 mN/m, σ_{L}^{D}=26.4 mN/m) was determined . One can calculated σ_{S}^{P} by equation (σ_{L}^{D})^{1/2}(σ_{S}^{D})^{1/2}+(σ_{L}^{P})^{1/2}(σ_{S}^{P})^{1/2}=σ_{L} (cos □+1)/2.

### Conductive Polymer Film I-B1

Film structure I-B1 was obtained by spin coating conductive polymer Ink-B6 on a ITO/Glass substrate.

### Conductive Polymer Film C-B1

Film structure C-B1 was obtained similarly as conductive polymer film I-B1, except that the film was annealed at 180° C. in air for 15 minutes.

TABLE B2
Conductive polymer ink film surface energy for Example B

| | | | σₛ | |
|---|---|---|---|---|
| | σₛ^{D} (mN/m) | σₛ^{P} (mN/m) | (mN/m) | |
| Conductive | Dispersive | Polar | Overall | Wetting |
| Polymer Film | component | component | Film | friendly Film? |
| I-B1 | 43.8 | 27.6 | 71.4 | Yes |
| C-B1 | 41.1 | 3.2 | 44.3 | No |

The data in Table B1 and B2 clearly demonstrated that by using the present inventive wet on wet process, inherently low surface energy conductive polymer materials such as fluoropolymer containing conductive polymer inks can be modified to make devices with improved life time and efficiency, yet wettable for the next layer material. Without wishing to be bound by any theory or explanation, it is believed that the increase of the surface energy of the conductive film was driven by the increase of the polar component of the surface energy.

### Example C

### Characterizing the Film Roughness and Film Structure Difference Between the Annealed and Unannealed Conducting Polymer Film

### Conductive Polymer Film I-C1

Film structure I-C1 was obtained by spin coating conductive polymer Ink-A1 on an ITO/Glass substrate. The spin speed was controlled so the film thickness was about 20 nm.

### Conductive Polymer Film I-C2

Film structure I-C2 was obtained by spin coating conductive polymer Ink-A1 on an ITO/Glass substrate. The spin speed was controlled so the film thickness was about 50 nm.

### Conductive Polymer Film I-C3

Film structure I-C3 was obtained by spin coating conductive polymer Ink-A1 on an ITO/Glass substrate. The spin speed was controlled so the film thickness was about 80 nm.

### Conductive Polymer Film I-C4

Film structure I-C4 was obtained by spin coating conductive polymer Ink-A1 on an ITO/Glass substrate. The spin speed was controlled so the film thickness was about 110 nm.

### Conductive Polymer Film C-C1

Film structure C-C1 was obtained similarly as conductive polymer film I-C1, except that the film was annealed at 180° C. in nitrogen for 15 minutes. The film thickness was about 20 nm.

### Conductive Polymer Film C-C2

Film structure C-C2 was obtained similarly as conductive polymer film I-C2, except that the film was annealed at 180° C. in nitrogen for 15 minutes. The film thickness was about 50 nm.

### Conductive Polymer Film C-C3

Film structure C-C3 was obtained similarly as conductive polymer film I-C3, except that the film was annealed at 180° C. in nitrogen for 15 minutes. The film thickness was about 80 nm.

### Conductive Polymer Film C-C4

Film structure C-C4 was obtained similarly as conductive polymer film I-C4, except that the film was annealed at 180° C. in nitrogen for 15 minutes. The film thickness was about 110 nm.

Atomic force microscopy (AFM) uses a pyramidal probe mounted on the underside of a cantilever to scan a sample surface. The probe itself is approximately a micron in size, with a nominal tip apex of 10-20 nm. Laser light (HeNe, ˜633 nm) is reflected off of the backside of the cantilever to a four-quadrant position sensitive diode detector (PSD). Close proximity or contact with the surface deflects the cantilever and this deflection is read by the PSD. Either absolute deflection (contact mode) or amplitude damping (tapping mode) provides the feedback input to keep a constant spacing between probe and sample, as the sample is scanned in a raster-pattern across the surface. The voltage required to maintain a constant deflection (or damping) is converted to a height, and thus a two-dimensional array of height values is collected. Tapping mode is accomplished by oscillating the cantilever at its resonant frequency, and then using some degree of damping as the feedback input. Phase imaging can be done in conjunction with tapping mode imaging; here, the phase lag between the excitation signal and the actual cantilever oscillation is passively monitored and displayed as an image. Contrast in phase images is due primarily to mechanical differences, e.g. elasticity and adhesion. AFM Instrument: Digital Instruments Dimension 3000 with a Nanoscope IIIa controller was used in the tapping mode with Sb doped Si springboard style cantilevers, Vistaprobes, Nanoscience instruments, (0.01-0.025 □/cm2, k˜40 N/m, cantilever length 125 □m and resonance frequency ˜350 kHz) as the probe type. Route-mean-squared roughness (Rq) values were derived from the topography images. As a note, contrast in the topography images indicates height differences, with higher regions appearing being lighter, and lower regions appearing darker. The height scales are shown below the corresponding topography image. Prior to performing surface roughness analyses, the images were flattened using a second order fitting algorithm to remove image artifacts due to vertical (Z) scanner drift, image bow, skips, and other vertical offsets between line scans.

Surface roughness measurement obtained form annealed and unannealed films made from conductive polymer dispersion Ink-Al has shown that the unannelaed film has a less smooth surface as compared to annealed film as shown in Table C. The surface roughness of the unannelaed film will help the adhesion of the semi-conducting polymer layer deposited on it. This adhesion is further enhanced during the drying/annealing step where the entire layer stack is exposed under elevated temperature.

TABLE C
Film surface roughness by AFM method for annealed and
unannelaed films

| | RMS Roughness (nm) | | | | |
|---|---|---|---|---|---|
| Conductive | | | | | |
| Polymer | Location | Location | | Average | |
| Films | 1 | 2 | Location 3 | RMS | Std. Dev. |
| I-C1 (un- | 2.0 | 1.9 | 1.9 | 1.9 | 0.1 |
| annealed) | | | | | |
| C-C1 | 1.6 | 1.8 | 1.8 | 1.7 | 0.1 |
| (annealed) | | | | | |
| I-C2 (un- | 1.6 | 1.7 | 1.6 | 1.6 | 0.1 |
| annealed) | | | | | |
| C-C2 | 1.2 | 1.1 | 1.0 | 1.1 | 0.1 |
| (annealed) | | | | | |
| I-C3 (un- | 1.3 | 1.5 | 1.5 | 1.4 | 0.1 |
| annealed) | | | | | |
| C-C3 | 0.9 | 1.1 | 1.0 | 1.0 | 0.1 |
| (annealed) | | | | | |
| I-C4 (un- | 1.5 | 1.4 | 1.4 | 1.4 | 0.1 |
| annealed) | | | | | |
| C-C4 | 1.1 | 0.9 | 1.1 | 1.0 | 0.1 |
| (annealed) | | | | | |

### Example D

### XPS Results from Layer Structures Formed by Spin Coating a Semi Conducting Polymer on Top of an Unannealed HIL Layer and an Annealed HIL Layer

X-Ray Photoemission Spectroscopy (XPS) provides atomic composition (element concentration and chemical state) of the top surface of solids. Under vacuum conditions, a monochromatic beam of X-rays is directed at the surface of the sample of interest, atoms are ionized by the X-rays and the kinetic energy of the photo-emitted electrons is measured with an analyzer. The relation between the kinetic energy of photoelectrons and the energy of X-ray photons provides a unique signature for each chemical element, its chemical state or bonding configuration. The XPS signal from a bulk material, following attenuation by a thin layer of some other material at its surface (e.g. the signal from the conductive polymer ink layer covered by a thin LEP layer) can be calculated using the Beer Lambert law. The signal from the bulk material detected at the surface, at some angle, □, to the surface normal, is given by: I=I₀ exp(−d/□ cos □). The XPS signal (from the conductive ink) having intensity I₀ will be attenuated to intensity I after traveling through a layer (of LEP) of thickness d. A skilled person in the art can use this method to measure thicknesses of overlying layers but also -when comparing samples with same overlying layer thickness- to infer whether the interface between the layers is abrupt or diffuse.

The XPS experiments were carried out on a Physical Electronics 5000 VersaProbe XPS spectrometer, which is equipped with multi-channel plate detectors (MCD) and a focused Al monochromatic X-ray source. The XPS data were collected using the Al k□ X-ray excitation (25 watts and 15 kV). The high-resolution spectra were collected at 23.50 eV pass energy, 50 msec dwell time, 0.1 eV/step. The analysis area was 100 □m at a take-off-angle □=90 deg. The quantitative elemental analyses were determined by measuring the peak areas from the spectra and applying the transmission-function corrected atomic sensitivity factors. The element detection limit is 0.1 atomic %, and the probing depth is less than 20 nm. The sample homogeneity was check by recording data at several locations and photoemission onset was used to verify homogeneity of the probed area.

In order to characterize the interface between the conductive polymer ink and the LEP layers, multi layer thin films were prepared by spin coating on 1″×1″ ITO/Glass substrates supplied by Colorado Concept Coatings LLC. ITO/Glass substrates were first cleaned by a combination of de-ionized water, detergent, methanol and acetone. Then the ITO/Glass substrates were treated with oxygen plasma in an SPI Prep II plasma etcher for about 10 min.

Film structure D1-ITO was obtained by spin coating conductive polymer Ink-A1 on an ITO/Glass substrate.

Film structure D2-ITO was obtained by spin coating conductive polymer Ink-A1 on an ITO/Glass substrate, followed by annealing it on a hot plate at 180° C. for 15 mins.

Film structure D3-ITO was obtained by spin coating conductive polymer Ink-A1 on an ITO/Glass substrate, followed by annealing it on a hot plate at 180° C. for 15 mins. Then a 28 nm±2 nm layer of semi-conducting polymer Lumation 1304 light emitting polymer from CDT was spin coated on top of the annealed HIL layer

Film structure D4-ITO was obtained by spin coating conductive polymer Ink-A1 on an ITO/Glass substrate, then a 28 nm±2 nm layer of semi-conducting polymer Lumation 1304 light emitting polymer from CDT was spin coated on top of the unannealed HIL layer.

TABLE D
relative atomic composition of film structures measured by XPS.

| | Relative atomic composition (%) | | | | |
|---|---|---|---|---|---|
| Film | Fluorine | Oxygen | Carbon | Sulfur | other |
| D1-ITO | 54.0 | 1.4 | 42.5 | 1.8 | 0.3 |
| D2-ITO | 56.2 | 4.5 | 37.2 | 1.9 | 0.2 |
| D3-ITO | 0 | 1.7 | 95.9 | 0.5 | 1.9 |
| D4-ITO | 1.4 | 1.8 | 94.0 | 0.5 | 2.3 |

Fluorine (F) was present only in the FSA polymer of the conductive polymer ink film and can therefore be used as a probe to investigate the bilayer (conductive polymer ink/LEP) structure. For sample D3-ITO, no F was detected which is consistent with the fact that the LEP layer is thicker than the probing depth of the XPS technique. In contrast, F was detected on sample D4-ITO indicating that F atoms have diffused into the LEP layer toward the film surface. This confirms the diffused/mixed interface between the conductive polymer ink layer and the LEP layer that can be obtained by the inventive wet on wet process.

While the invention has been described with reference to certain aspects or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method for manufacturing an organic electronic device comprising:
a) providing an anode,
b) depositing a conducting polymer on the anode to form a hole-injection layer,
c) depositing the semi-conducting layer on the hole injection layer, and
d) applying these layers under conditions sufficient to form an interfacial bond between the hole injection layer and the semi-conducting layer.
e) providing a cathode,

2. The method of claim 1 wherein the device comprises an organice light emitting device.

3. The method of claim 1 wherein the conducting polymer comprises at least one polythiophene.

4. The method of claim 3 wherein the conducting polymer comprises a dispersion comprising said polythiophene and at least one member selected from the group consisting of PSSA and polymeric sulfonic acids.

5. The method of claim 3 wherein the polymeric sulfonic acids comprise at least one of Poly(2-acrylamido-2-methyl-1-propanesulfonic acid) and (PAAMPS).

6. The method of claim 1 wherein the semi-conducting layer comprises a light emitting polymer.

7. The method claim 4 wherein said dispersion further comprises at least one additive in an amount sufficient to increase film surface energy.

8. The method of claim 1 further comprising annealing the hole-injection layer prior to depositing the semi-conducting layer.

9. An organic electronic device comprising:
an anode, a cathode, a semiconducting layer between the anode and the cathode and a hole injection layer comprising a conducting polymer between the anode and the semi-conducting layer; where an interfacial bonding layer is formed between the hole injection layer and the semi-conducting layer.

10. The device of claim 9 wherein the device comprises an organic light emitting device.

11. The device of claim 9 wherein the interfacial bonding layer comprises a hole injection rich area and semi-conducting rich area.

12. The device of claim 9 wherein the semi-conducting layer comprises a light emitting polymer.

13. The device of claim 9 wherein the interfacial bonding layer comprises a mixture of the hole injection layer and the semi-conducting layer which is detectable by XPS.

14. The method of claim 3 wherein the polythiophene comprises at least one member selected from the group consisting of polyethylenedioxythiophenes and polythienothiophenes.
